(19) United States
(12) Patent Application Publication
(10) Pub. No.: US 2024/0397615 A1
(43) Pub. Date: Nov. 28, 2024

(54) CIRCUIT BOARD UNIT AND IMAGE FORMING APPARATUS

(71) Applicant: CANON KABUSHIKI KAISHA, Tokyo (JP)

(72) Inventor: MASAHIRO SHINOTSUKA, Ibaraki (JP)

(21) Appl. No.: 18/648,872

(22) Filed: Apr. 29, 2024

(30) Foreign Application Priority Data
May 24, 2023 (JP) 2023-085413

(51) Int. Cl. H05K 1/02; G03G 15/00; G03G 15/01; H05K 1/14

(52) U.S. Cl. CPC H05K 1/0296; G03G 15/0121; G03G 15/0189; G03G 15/50; G03G 15/80; H05K 1/144; H05K 2201/042

(57) ABSTRACT

A circuit board unit is disclosed, which includes a first circuit board having a first signal connector and an inter circuit board connector, the first signal connector and the inter circuit board connector being configured to be capable of outputting a first signal; and a second circuit board having a second signal connector configured to be capable of outputting a second signal. In a connector inserting and pulling direction of the first signal connector, the first circuit board and the second circuit board are disposed overlapping with each other such that the second circuit board covers a connector outlet of the first circuit connector.

### BACKGROUND OF THE INVENTION

### Field of the Invention

This invention relates to a circuit board unit to be provided in an apparatus main body and an image forming apparatus having the circuit board unit.

### Description of the Related Art

Conventionally, in a main body of an apparatus such as an image forming apparatus, multiple circuit boards that respectively perform control functions. In such an image forming apparatus, circuit boards are connected to each other with harnesses or FFCs (Flexible Flat Cables) so that communications are made between the circuit boards by sending and receiving necessary signals. However, in these image forming apparatus in which circuit boards are connected to each other with harnesses or FFCs, there are limits in cost reduction and space saving.

In view of the above, Japanese Patent Application Laid-Open No. 2004-128017 discloses a method of connecting circuit boards using an inter circuit board connector. Specifically, in Japanese Patent Application Laid-Open No. 2004-128017, a first circuit board and a second circuit board are placed in parallel and an inter circuit board connector provided on the first circuit board is fitted into an inter circuit board connector provided on the second circuit board so that the first circuit board and the second circuit board are electrically connected. In Japanese Patent Application Laid-Open No. 2004-128017, spacers are provided between the first circuit board and the second circuit board to support the first circuit board and the second circuit board at the positions other than the inter circuit board connectors.

Furthermore, in Japanese Patent Application Laid-Open No. 2004-128017, a connector of a positional misalignment absorbing type is used as one of the inter circuit board connectors provided on the first circuit board and the second circuit board, so that the positional misalignment between the two connectors are absorbed. As a result, space-saving is realized while the cost required for the FFCs can be reduced.

However, Japanese Patent Application Laid-Open No. 2004-128017 has a problem that when using the first circuit board that is located under the second circuit board, the workability deteriorates due to the bad visibility for the connector provided on the first circuit board.

### SUMMARY OF THE INVENTION

The purpose of the present invention is to provide a circuit board unit that can improve workability more than before with a configuration in which circuit boards are disposed, overlapping with each other.

A circuit board unit according to the present invention, comprising:
a first circuit board having a first signal connector and an inter circuit board connector, the first signal connector and the inter circuit board connector being configured to be capable of outputting a first signal; and a second circuit board having a second signal connector configured to be capable of outputting a second signal, wherein in a connector inserting and pulling direction of the first signal connector, the first circuit board and the second circuit board are disposed overlapping with each other such that the second circuit board covers a connector outlet of the first circuit connector, wherein the first signal is input from the first circuit board to the second circuit board via the inter circuit board connector, and wherein the second signal connector outputs the first signal and the second signal.

Further features of the present invention will become apparent from the following description of exemplary embodiments with reference to the attached drawings.

### BRIEF DESCRIPTION OF THE DRAWINGS

FIG. 1 is a schematic diagram showing the configuration of an image forming apparatus according to an embodiment of the present invention.

FIG. 2 is a block diagram of the image forming apparatus according to the embodiment of the present invention.

FIG. 3 is a diagram showing a perspective view of a slot where a second circuit board of the circuit board unit according to the embodiment of the present invention is not used.

FIG. 4 is a schematic diagram showing the configuration in which a first circuit board is connected to a main board of the circuit board unit according to the embodiment of the present invention.

FIG. 5 is a diagram showing a perspective view of a slot where the second circuit board of the circuit board unit according to the embodiment of the present invention is used.

FIG. 6 is a block diagram showing the configuration of the circuit board unit according to the embodiment of the present invention.

FIG. 7 is a diagram showing a perspective view of a part of the circuit board unit according to the embodiment of the present invention.

FIG. 8A is a diagram showing a plan view of a slot of the circuit board unit according to the embodiment of the present invention. FIG. 8B is a diagram showing a side view of the slot of the circuit board unit according to the embodiment of the present invention.

### DESCRIPTION OF THE EMBODIMENTS

Hereinafter, with reference to the drawings, embodiments of the present invention will be described in detail.

### <Configuration of Image Forming Apparatus>

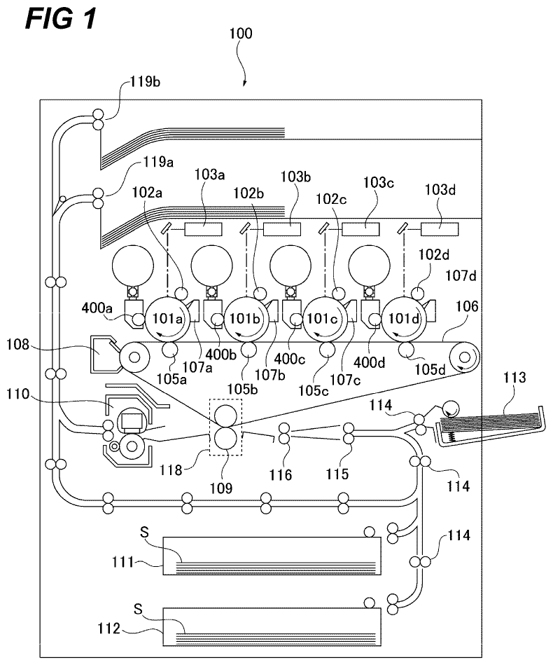

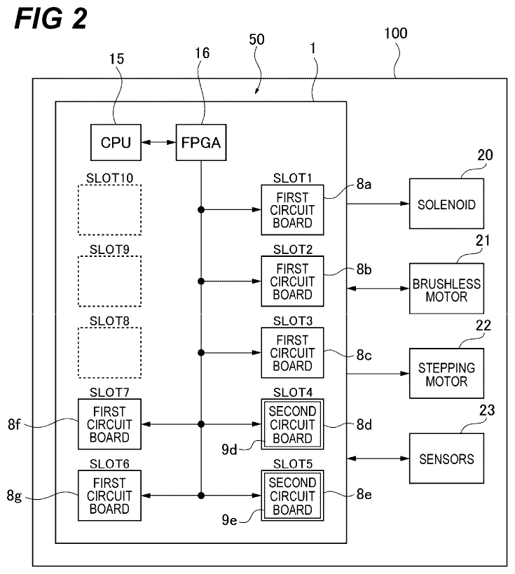

The configuration of the image forming apparatus 100 according to an embodiment of the present invention will be described referring to FIGS. 1 and 2.

The image forming apparatus 100 is exemplified as a color image forming apparatus using electrophotographic system and has four parallel-arranged image forming portions that respectively form toner images of the colors of yellow, magenta, cyan, and black. The configurations of the image forming portions are the same as each other, but the colors of toner used in the image forming portions are different from each other.

The image forming apparatus 100 has the solenoid 20, the brushless motor 21, the stepping motor 22, the sensors 23, the circuit board unit 50, the photosensitive drums 101a, 101b, 101c, and 101d, the charging rollers 102a, 102b, 102c, and 102d, the laser scanners 103a, 103b, 103c, and 103d, the primary transfer rollers 105a, 105b, 105c, and 105d, the intermediate transfer belt 106, the drum cleaners 107a, 107b, 107c, and 107d, the intermediate transfer belt cleaner 108, the fixing device 110, the sheet feeding cassettes 111 and 112, and the conveying rollers 114.

The image forming apparatus 100 further has the rollers before registration 115, the registration rollers 116, the secondary transfer portion 118, the discharge portions 119a, and 119b, and the developing devices 400a, 400b, 400c, and 400d. The solenoid 20, the brushless motor 21, and the stepping motor 22 are actuators and loads disposed in the image forming apparatus 100.

The solenoid 20 drives pickup rollers that pick up the recording materials S accommodated in the sheet feeding cassette 111 or 112 under control of the CPU 15 of the circuit board unit 50, which will be described later.

The brushless motor 21 drives the developing devices 400a, 400b, 400c, and 400d under control of the CPU 15.

The stepping motor 22 drives the developing devices 400a, 400b, 400c, and 400d under control of the CPU 15.

The sensors 23 outputs an electric signal corresponding to the temperature detected by temperature sensors that detect the temperature of the fixing device 110.

Electronic components such as the CPU 15 (which will be described later) that controls the overall operation of the image forming apparatus 100 are provided on the circuit board unit 50. The detailed configuration of the circuit board unit 50 will be described later.

The photosensitive drums 101a, 101b, 101c, and 101d rotate in the direction indicated by the arrows in FIG. 1.

The charging rollers 102a, 102b, 102c, and 102d uniformly charge the photosensitive drums 101a, 101b, 101c, and 101d, respectively.

The laser scanners 103a, 103b, 103c, and 103d irradiate the uniformly charged photosensitive drums 101a, 101b, 101c, and 101d with laser beam corresponding to image signals of respective colors. As a result, electrostatic latent images are formed on the photosensitive drums 101a, 101b, 101c, and 101d.

The primary transfer rollers 105a, 105b, 105c, and 105d sequentially transfer the toner images formed on the photosensitive drums 101a, 101b, 101c, and 101d to the intermediate transfer belt 106, so that a full-color toner image is formed on the intermediate transfer belt 106.

The intermediate transfer belt 106, which is configured to be endless and rotatable, conveys the full-color toner image formed by the primary transfer rollers 105a, 105b, 105c, and 105d.

The drum cleaners 107a, 107b, 107c, and 107d collect after-transfer residual toner on the photosensitive drums 101a, 101b, 101c, and 101d.

The intermediate transfer belt cleaner 108 collects after-transfer residual toner on the intermediate transfer belt 106, which has not been transferred by the secondary transfer portion 118.

The fixing device 110 fixes a toner image transferred onto the recording material S to the recording material S by heating and pressurizing the recording material S that is conveyed by the secondary transfer portion 118 and onto which the toner image is transferred. The fixing device 110 conveys the recording material S onto which the toner image is transferred to the discharge portion 119a or 119b.

The sheet feeding cassette 111 accommodates recording materials S. When the image forming apparatus 100 starts the image forming operation, a recording material S is fed from the sheet feeding cassette 111 to the conveying rollers 114.

The sheet feeding cassette 112 accommodates recording materials S. When the image forming apparatus 100 starts the image forming operation, a recording material S is fed from the sheet feeding cassette 111 to the conveying rollers 114.

The conveying rollers 114 convey the recording material S that has been fed by the sheet feeding cassette 111 or 112 to the rollers before registration 115.

The rollers before registration 115 convey the recording material S that has been conveyed by the conveying rollers 114 to the registration rollers 116.

The registration rollers 116 correct the skew feeding of the recording material S that has been conveyed by the rollers before registration 115, and temporarily stop the conveyance of the recording material S. The registration rollers 116 convey the recording material S to the secondary transfer portion 118 at the timing adjusted such that a toner image on the intermediate transfer belt 106 should be transferred on a desired position of the recording material S.

The second transfer portion 118 includes the second transfer roller 109. In the second transfer portion 118, a toner image on the intermediate transfer belt 106 is transferred by the secondary transfer roller 109 to the recording material S conveyed by the registration rollers 116. The recording material S on which a toner image has been transferred is conveyed to the fixing device 110 by the secondary transfer roller 109 of the secondary transfer portion 118.

The discharge portion 119a discharges the recording material S having been conveyed by the fixing device 110 outside the apparatus main body of the image forming apparatus 100.

The discharge portion 119b discharges the recording material S having been conveyed by the fixing device 110 outside the apparatus main body of the image forming apparatus 100.

The developing devices 400a, 400b, 400c, and 400d develop electrostatic latent images with toners of yellow, magenta, cyan, and black formed on the photosensitive drums 101a, 101b, 101c, and 101d, respectively. As a result, toner images are formed the photosensitive drums 101a, 101b, 101c, and 101d. The developing devices 400a, 400b, 400c, and 400d are configured as a cartridge type in order that the exchange of components becomes easy.

### <Configuration of Circuit Board Unit>

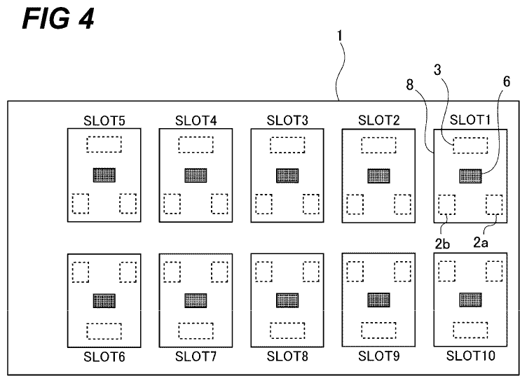

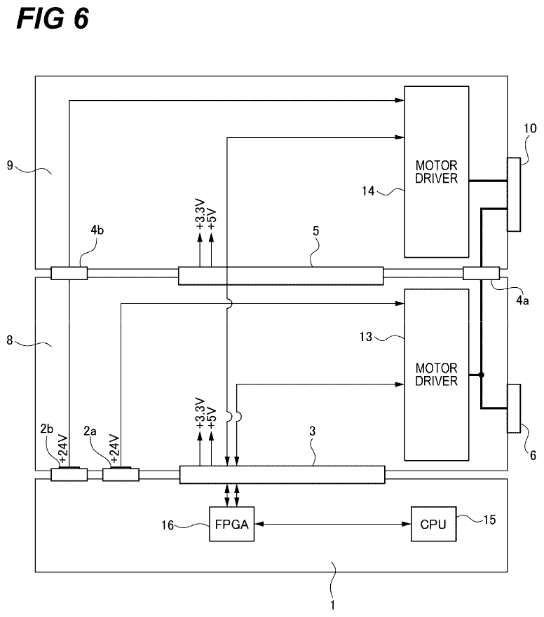

The configuration of the circuit board unit 50 according to the embodiment of the present invention will be described in detail referring to FIGS. 2 to 7.

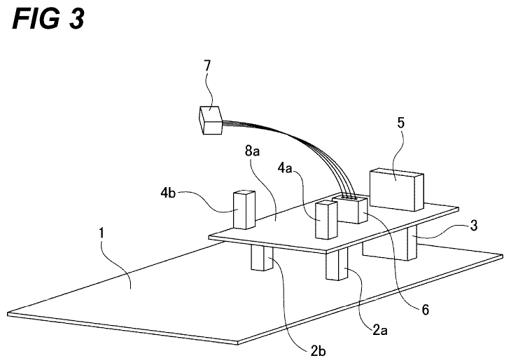

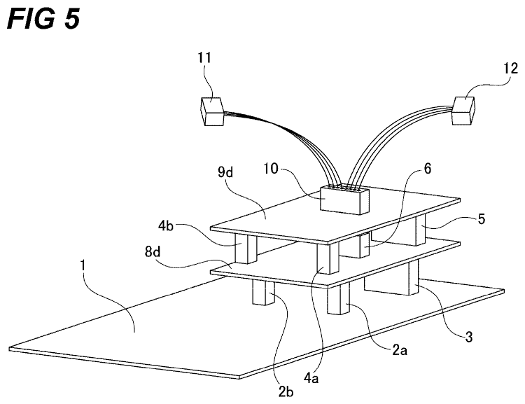

FIG. 3 indicates the configuration of the slots SLOT1 to SLOT3, SLOT6, and SLOT7 of the circuit board unit 50. FIG. 5 indicates the configuration of the slots SLOT4 and SLOT5 of the circuit board unit 50. In FIGS. 2, 3, and 5, the first circuit boards 8a, 8b, 8c, 8d, 8e, 8g and 8f respectively indicate the first circuit boards 8 in the slots SLOT1 to SLOT7. In FIGS. 2 and 5, the second circuit boards 9d and 9e indicate the second circuit boards 9 in the slots SLOT4 and SLOT5.

The circuit board unit 50 is provided in the apparatus main body of the image forming apparatus 100. The circuit board unit 50 includes the main board 1, the power connectors 2a and 2b, the signal connector 3, and the additional connectors 4a and 4b, the additional signal connector 5, the first load connectors 6 and 7, the first circuit board 8, the second circuit board 9, and the second load connectors 10, 11. The second circuit board 9, the second load connectors 10, 11, and the first load connector 12 are provided if necessary. If these components are not necessary, they are not provided.

The main board 1 includes a circuit (not shown) for performing operational sequences of the image forming apparatus 100 to overall control the image forming apparatus 100. The main board 1 works as the master when controlling the loads of the image forming apparatus 100. The main board 1 has a function to drive the loads in the image forming apparatus 100 as well as a function to analyze the information collected by the sensors 23. The loads include the solenoid 20, the brushless motor 21, and the stepping motor 22, for example.

The main board 1 supplies power source voltage to the first circuit board 8 via the power connectors 2a and 2b. The main board 1 transmits signals to the first circuit board 8 via the signal connector 3 and receives signals from the first circuit board 8 via the connector 3. The main board 1 supplies power source voltage to the second circuit board 9 via the power connector 2b, the first circuit board 8, and the additional connector 4b. The main board 1 transmits signals to the second circuit board 9 via the signal connector 3, the first circuit board 8, and the additional signal connector 5, and receives signals from the second circuit board 9 via the first circuit board 8 and the additional signal connector 5.

Specifically, the main board 1 includes the CPU 15 and FPGA (Field-Programmable Gate Array) 16.

The CPU 15 controls the operation of the FPGA 16 by communicating with the FPGA 16.

The FPGA 16 outputs the control signal for controlling the drive of the loads in the image forming apparatus 100 to the motor driver IC13 (which will be described later) of the first circuit board 8 via the signal connector 3 by communicating with the CPU 15 to follow the control of the CPU 15. The FPGA 16 further outputs the control signal for controlling the drive of the loads in the image forming apparatus 100 to the motor driver IC14 (which will be described later) of the second circuit board 9 via the signal connector 3 and the additional signal connector 5 by communicating with the CPU 15 to follow the control of the CPU 15.

The FPGA 16 analyses the digital signal input from the motor driver IC 13 via the signal connector 3. The FPGA 16 analyses the digital signal input from the motor driver IC 14 via the signal connector 3 and the additional signal connector 5.

The power source connector 2a is an inter circuit board connector and a plug of the power source connector 2a is mounted on the first circuit board 8 is fitted into a socket mounted on the main board 1. When the plug of the power source connector 2a is fitted into the socket mounted on the main board 1, the main board 1 and the first circuit board 8 are electrically connected without using harness or FFC.

The power source connector 2b is an inter circuit board connector and the plug of the power source connector 2b mounted on the first circuit board 8 is fitted into the socket mounted on the main board 1. The plug and the socket of the power source connector 2b are different from the ones of the power source connector 2a. When the plug of the power source connector 2b mounted on the first circuit board 8 is fitted into the socket for the power source connector 2b mounted on the main board 1, the main board 1 and the first circuit board 8 are electrically connected to each other without using harness or FFC.

The signal connector 3 includes a plug that is different from the ones of the power source connectors 2a and 2b. The plug of the signal connector 3 is mounted on the first circuit board 1. The signal connector 3 includes a socket that is different from the ones of the power source connectors 2a and 2b. The signal connector 3 is an inter circuit board connector and the plug of the signal connector 3 is fitted into the socket of the signal connector 3. When the plug of the signal connector 3 mounted on the first circuit board 8 is fitted into the socket of the signal connector 3 mounted on the main board 1, the main board 1 and the first circuit board 8 is electrically connected to each other without using harness or FFC.

The main board 1 includes the sockets for the power source connectors 2a and 2b, and the signal connector 3 in slots SLOT, respectively. The first circuit board 8 is connected to the slot SLOT by a common IF (interface). It is not necessary for the first circuit board 8 to be connected to all the slots SLOT. It suffices that the number of the first circuit boards 8 necessary for the image forming apparatus are connected to the slots SLOT. Slots SLOT with which first circuit boards 8 are not connected is referred to as vacant slots (for example, slots SLOT8 to SLOT10 in FIG. 2 are vacant slots).

The number of the slots SLOT is exemplified as 10 (slots SLOT1 to SLOT10). Further, the number of the slots SLOT depends on the I/O resource of FPGA 16 and the number is not limited to 10 but the number of slots SLOT other than 10 can be provided according to the I/O resource of the FPGA 16.

The additional connector 4a is an inter circuit board connector and a plug of the additional connector 4a mounted on the second circuit board 9 is fitted into a socket mounted on the first circuit board 8. When the plug of the additional connector 4a is fitted into the socket mounted on the first circuit board 8, the first circuit board 8 and the second circuit board 9 are electrically connected to each other without using harness or FFC. When the first circuit board 8 and the second circuit board 9 are electrically connected to each other, the driving signal generated by the motor driver IC 13 on the first circuit board 8 is input to the second load connector 10 on the second circuit board 9 via the additional connector 4a.

The additional connector 4b is an inter circuit board connector and the plug of the additional connector 4b mounted on the second circuit board 9 is fitted into the socket mounted on the first circuit board 8. The plug and the socket of the additional connector 4b are different from the ones of the additional connector 4a. When the plug of the additional connector 4b mounted on the second circuit board 9 is fitted into the socket for the additional connector 4b mounted on the first circuit board 8, the first circuit board 8 and the second circuit board 9 are electrically connected to each other without using harness or FFC.

The additional signal connector 5 includes a plug that is different from the ones of the additional connectors 4a and 4b. The plug of the additional signal connector 5 is mounted on the second circuit board 9. The addition signal connector 5 includes a socket that is different from the ones of the additional connectors 4a and 4b. The plug of the additional signal connector 5 is mounted on the first circuit board 8.

The additional signal connector 5 is an inter circuit board connector and the plug of the additional signal connector 5 mounted on the second circuit board 9 is fitted into the socket of the additional signal connector 5 mounted on the first circuit board 8. When the plug of the additional signal connector 5 mounted on the second circuit board 9 is fitted into the socket of the addition signal connector 5 mounted on the first circuit board 8, the first circuit board 8 and the second circuit board 9 are electrically connected to each other without using harness or FFC.

The first load connector 6 as the first signal connector is mounted on the first circuit board 8. When the first circuit board 8 and the second circuit board 9 are electrically connected to each other, the first load connector 6 is not connected to the load via harness or FFC. The first load connector 6 is capable of outputting the driving signal generated by the motor driver IC 13. The first load connector 6 is not connected to any parts outside the first circuit board 8.

The first load connector 7 is connected to the first load connector 6 via wires as shown in FIG. 3. Further, the first load connector 7 is connected to the load to be controlled. When the second circuit board 9 is provided, the first load connector 7 is not necessary (see FIG. 5). In FIG. 2 for example, the first load connector 7 is provided only to the first circuit boards 8a, 8b, 8c, 8f, and 8g where the second circuit boards 9 are not provided.

The first circuit board 8 has the function to drive and control one load in the image forming apparatus 100 by the control signal input from the FPGA 16. The first circuit board 8 is disposed above and in parallel with the main board 1. The first circuit board 8 is connected to the main board 1 via the power source connectors 2a and 2b, and the signal connector 3. The first circuit board 8 includes the motor driver IC 13 as a first circuit.

The motor driver IC 13 works when power is supplied to the motor driver IC 13 from a power supply (not shown) on the main board 1.

When the second circuit board 9 is not used, the motor driver IC 13 generates a driving signal as a first signal for driving the load based on a control signal input from the FPGA 16 via the signal connector 3. The motor driver IC 13 drives the load connected to the first load connector 7 by outputting the generated driving signal to the load via the first load connectors 6 and 7. The motor driver IC 13 converts the analog signal input from the sensors 23 via the first load connectors 6 and 7 into the digital signal and outputs this digital signal to the FPGA 16 via the signal connector 3. In this way, the driving signal generated by the motor driver IC13 includes a signal for controlling the load that is driven and controlled by the first circuit board 8. The signal for controlling the load, included in the driving signal generated by the motor driver IC 13 is, for example, a signal for controlling the solenoid 20, and at least one of first motors of the brushless motor 21 and stepping motor 22.

When the second circuit board 9 is used, the motor driver IC 13 generates a driving signal for driving the load based on a control signal input from the FPGA 16 via the signal connector 3. The motor driver IC 13 drives the load connected to the first load connector 12 by outputting the generated driving signal to the load via the additional connector 4a, the second load connector 10, and the first load connector 12.

The motor driver IC 13 converts the analog signal input from the sensors 23 via the first load connector 12, the second load connector 10, and the additional connector 4a into the digital signal and outputs this digital signal to the FPGA 16 via the signal connector 3.

Although the common IFs of the power source connectors 2a and 2b, and the signal connector 3 are used, the first circuit boards 8 have different circuit configurations depending on loads to be controlled. Specifically, the first circuit board 8 to be used for driving and controlling the actuators and the circuit board 8 to be used for driving and controlling the sensors 23 are different in functions, and therefore have circuit configurations different from each other. FIG. 2 exemplarily shows that seven first circuit boards 8a, 8b, 8c, 8d, 8e, 8f, and 8g are connected to seven slots SLOT out of the all ten slots SLOT.

The second circuit board 9 is provided for performing an additional function and is not used when additional functions are not necessary. FIG. 2 exemplarily shows that the second circuit boards 9 are provided only in the slots SLOT4 and SLOT5. The second circuit boar 9 has the function to drive and control one load (second load) different from the one load (first load) that is driven and controlled by the first circuit board 8 in the image forming apparatus 100 by the control signal input from the FPGA 16.

The second circuit board 9 is disposed above and in parallel with the first circuit board 8. The second circuit board 9 is connected to the first circuit board 8 via the additional connectors 4a and 4b, and the additional signal connector 5. The second circuit board 9 includes the motor driver IC 14 as a second circuit. The second circuit board 9 is disposed overlapping with the first circuit board 8 such that the second circuit board 9 covers the connection port of the first load connector 6 in the inserting and pulling directions.

The motor driver IC 14 works when power is supplied to the motor driver IC 14 from the first circuit boar 8 via the additional connector 4b. The power for driving the electronic components such as the motor driver IC 14 mounted on the second circuit board 9 is supplied from the first circuit board 8 via the additional connector 4b to the second circuit board 9.

The motor driver IC 14 generates a driving signal as a second signal for driving the load based on a control signal input from the FPGA 16 via the signal connector 3 and the additional signal connector 5. The motor driver IC 14 drives the load connected to the second load connector 11 by outputting the generated driving signal to the load via the second load connectors 10 and 11. The motor driver IC 14 converts the analog signal input from the sensors 23 via the second load connectors 10 and 11 into the digital signal and outputs this digital signal to the FPGA 16 via the signal connector 3 and additional signal connector 5. In this way, the driving signal generated by the motor driver IC14 includes a signal for controlling the load that is driven and controlled by the second circuit board 9. The signal for controlling the load, included in the driving signal generated by the motor driver IC 14 is, for example, a signal for controlling the solenoid 20, and at least one of second motors of the brushless motor 21 and stepping motor 22.

The second load connector 10 as a second signal connector is mounted on the second circuit board 9. The second load connector 10 is capable of outputting the driving signal generated by the motor driver IC 14.

The second load connector 11 is connected to the second load connector 10 via wires and is connected to the load to be controlled.

The first load connector 12 is connected to the second load connector 10 via wires and is also connected to the load to be controlled that is different from the one connected to the second load connector 11.

In the circuit board unit 50, which has the above configuration, the motor driver IC 13 of the first circuit board 8 and the motor driver IC 14 of the second circuit board 9 perform the functions necessary for the image forming apparatus 100 by controlling their respective loads.

The set of the power connectors 2a and 2b, and the signal connector 3 is always provided when the first circuit board 8 is connected to the main board 1. In this case, even if one of the power connectors 2a and 2b is not necessary, the main board 1 and the first circuit board 8 are connected to each tother by these three connectors in order to hold the main board 1 and the first board 8.

The IFs to which the first circuit boards 8 are connected are limited to ten slots SLOT in the main board, whereas the second circuit boards 9 can be added to the first circuit boards 8 if vacant I/O ports are available. Therefore, the resources of the slots SLOT can be effectively utilized.

The circuit board unit 50 has the number of I/O ports for driving two loads at most by means of the power connectors 2a and 2b, and the signal connector 3.

The circuit board unit 50 should be configured such that the only one of the first load connector 6 and the additional signal connector 5 is exclusively connected the outside of the first circuit board 8 and the other of the first load connector 6 and the additional signal connector 5 is not connected to a connection target of the outside of the first circuit board 8.

### <Operation of Circuit Board Unit>

The operation of the circuit board unit 50 according to the embodiment of the present invention will be described in detail referring to FIGS. 2 to 5.

When only the first circuit board 8 is used since there is only one load as control target, the circuit board unit 50 outputs a driving signal for driving the load from the first load connector 6. For example, the circuit board unit 50 outputs a driving signal for driving the stepping motor 22 as a first motor from the first load connector 6.

In contrast, when the first circuit board 8 and the second circuit board 9 are used since there are two loads as control targets, the first load connector 6 mounted on the first circuit board 8 is hidden under the second circuit board 9. In this case, the operation of connecting a harness connected to a load to the first load connector 6 mounted on the first circuit board 8 is difficult since there is only a small working space.

In view of the above, when the first circuit board 8 and the second circuit board 9 are used, driving signals for driving two loads are output from the second load connector 10 without using the first load connector 6. In this case, the driving signal output from the first load connector 6 mounted on the first circuit board 8 to the load is input to the second load connector 10 via the additional connector 4a. For example, the circuit board unit 50 outputs a driving signal for driving the stepping motor 22 as a first motor and outputs a driving signal for driving the other stepping motor 22 as a second motor from the second load connector 10.

### <Arrangement of First Load Connector on First Circuit Board>

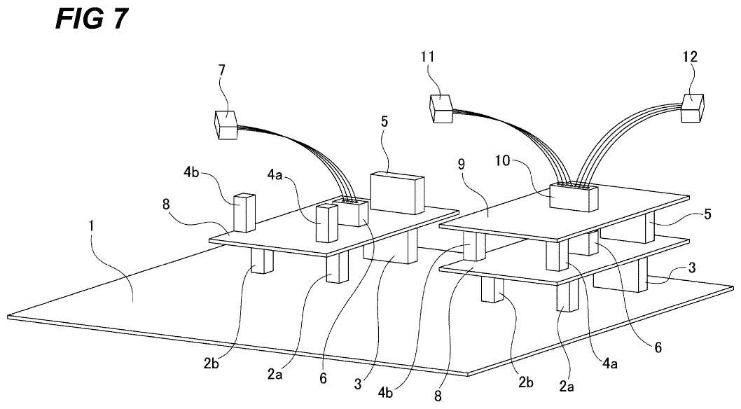

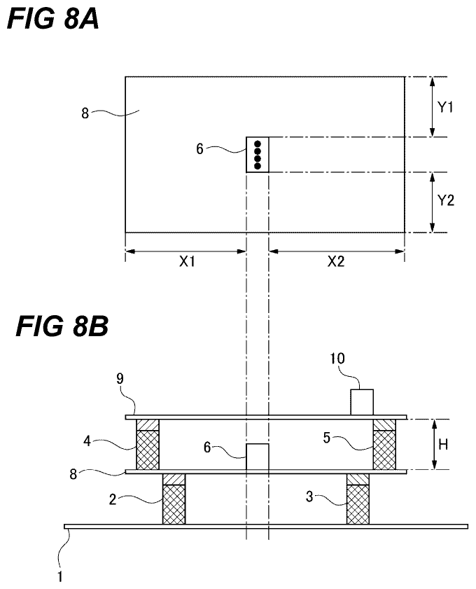

The arrangement of the first load connector 6 on the first circuit board 8 of the circuit board unit 50 according to the embodiment of the present invention will be described in detail referring to FIGS. 7 and 8.

The FIG. 8A is a diagram showing a plan view of the circuit board unit 50 from which the second circuit board 9 on a slot of the circuit board unit 50 is removed. The FIG. 8B is a diagram showing a side view of the slot of the circuit board unit 50. In FIG. 8B, the power connectors 2a and 2b are collectively denoted as power connectors 2 and the additional connectors 4a and 4b are collectively denoted as additional connectors 4.

The first circuit board 8 is disposed above and in parallel with the main board 1. The main board 1 and the first circuit board 8 are electrically connected to each other by the power connectors 2a and 2b, and the signal connector 3 without using harness or FFC.

When a function should be added for the first circuit board 8, the second circuit board 9 is connected to the first circuit board 8. In this case, the second circuit board 9 is disposed above and in parallel with the first circuit board 8. The first circuit board 8 and the second circuit board 9 are electrically connected to each other by the additional connectors 4a and 4b, and the additional signal connector 5a without using harness or FFC.

The respective loads connected with a harness by the second load connectors 11 and the first load connector 12 are controlled by driving signals output from the second load connector 10 mounted on the second circuit board 9.

When it is not necessary to add a function to the first circuit board 8, a second circuit board 9 is not connected to the first circuit board 8. A signal is output from the first load connector 6 to the first load connector 7 connected to the load from the first circuit board 8.

As shown in FIG. 7, the first circuit boards 8 which control the same kind of loads are sometimes disposed adjacent to each other, like a slot in which the first circuit board 8 and the second circuit board 9 are used and a slot in which only the first circuit board 8 is used. In this case, it is in the right state that the first load connector 6 mounted on the first circuit board 8 in the slot where the first circuit board 8 and the second circuit board 9 are used is not used.

However, there is a possibility that the connector which should be inserted into the first load connector 6 in the slot where only the first circuit board 8 is used may be wrongly inserted into the first load connector 6 in the adjacent slot where the first circuit board 8 and the second circuit board 9 are used. In this way, when a wrong connector is inserted, the image forming apparatus 100 becomes in an abnormal state due to a wrong connection.

Therefore, in the arrangement shown in FIG. 7 where the first circuit boards 8 for controlling the same kind of loads are disposed adjacent to each other, the first load connector 6 is disposed from the opposing two edges out of the four edges of the first circuit boards 8 for a distance according to the distance between the first circuit board 8 and the second circuit board 9.

First, the arrangement of the first load connector 6 on the first circuit board 8 in a case where the distance H between the first circuit board 8 and the second circuit board 9 is 10 mm or less will be described.

In this case, when the distances from the opposing two short edges out of the four edges of the first circuit board 8 to the end portions of the first load connector 6 are given as X1 and X2, it is preferable that the first load connector 6 is disposed such that X1≥5 mm and X2≥5 mm. When the distances from the opposing two long edges to the end portions of the first load connector 6 are given as Y1 and Y2, it is preferable that the first load connector 6 is disposed such that Y1≥5 mm and Y2≥5 mm.

When H≤10 mm, there is only a space which a finger of a grown-up can barely enter between the first circuit board 8 and the second circuit board 9, so that an operation cannot be performed by holding a connector. Therefore, when the distances X1, X2, Y1, and Y2 are ensured to be greater than or equal to 5 mm, it is difficult for a wrong connecter to be inserted into the first load connector 6 which should not be used.

Next, the arrangement of the first load connector 6 on the first circuit board 8 in a case where the distance H between the first circuit board 8 and the second circuit board 9 in the inserting/pulling direction of the first load connector 6 is greater than 10 mm will be described.

In this case, it is preferable for the first load connector 6 to be disposed such that the distances X1 and X2 from the edges of the first circuit board 8 to the first load connector 6 are greater than or equal to 10 mm in the direction perpendicular to the connector inserting/pulling direction of the first load connector 6. Further, it is preferable for the first load connector 6 to be disposed such that the distances Y1 and Y2 from the edges of the first circuit board 8 to the first load connector 6 are greater than or equal to 10 mm in the direction perpendicular to the connector inserting/pulling direction of the first load connector 6. In this case, even when there is a space that a finger can enter between the first circuit board 8 and the second circuit board 9, there is not an enough space for fingers with which a connector is inserted into the first load connector 6. As a result, it is difficult for a wrong connecter to be inserted into the first load connector 6.

In this way, misconnection of connectors can be prevented by the configuration in which the first load connector 6 that should not be used cannot be accessed.

The above figures are approximate values and it is sufficient that there is not an enough space that a finger can enter for inserting a connector between the first circuit board 8 and the second circuit board 9, so that it is difficult for a connector to be inserted into the first load connector 6.

By the way, in Japanese Patent Application Laid-Open No. 2004-128017, the connection of the connector mounted on the first circuit board can be incomplete. In such a case, there is a possibility that after a product is shipped without noticing an incomplete connection of a connector, a failure of electrical contact occurs at a destination site due to vibrations during transporting the product, which properly worked at the production site.

In Japanese Patent Application Laid-Open No. 2004-128017, a connection failure may occur due to disconnection or incomplete connection of connectors mounted on the first circuit board after an exchange of circuit boards by a service person. In this case, it might take a longer time to recover the failure without noticing the disconnection or the incomplete connection of the connector, which could give a great inconvenience to a user.

In the present embodiment, the first circuit board 8 inputs a driving signal output from the motor driver IC 13 to the second load connector 10 via the additional connector 4a. Further, the second load connector 10 outputs a driving signal output from the motor driver IC 14 to the second load, and outputs a driving signal output from the motor driver IC 13 and input to the second load connector 10 via the additional connector 4a to the first load. As a result, in the configuration in which multiple circuit boards are disposed overlapping with each other, a connection failure due to a decrease in workability and visibility for the first load connector 6 can be prevented.

Further, in the present embodiment, space-saving can be realized by effectively utilizing the space on the first circuit board 8 by disposing the first circuit board 8 and the second circuit board 9 in the vertical direction such that these circuit boards are in parallel with each other.

The present invention is not limited to the above embodiment and can be varied within the gist of the present invention.

Specifically, in the above embodiment, the main board 1 and the first circuit board 8 are connected to each other by the power connectors 2a and 2b, and the signal connector 3. However, the present invention is not limited to this configuration and the main board 1 and the first circuit board 8 can electrically connected to each other by one, two, four, or more than four inter circuit board connector(s) without using harness or FFC.

Further, in the above embodiment, the technology disclosed here is applied to the color image forming apparatus of an electrophotographic system. However, the technology disclosed here can be applied to an image forming apparatuses of other systems such as an ink jet system.

Further, in the above embodiment, the circuit board unit 50 is provided in an image forming apparatus. However, the circuit board unit 50 can be provided in the apparatus other than the image forming apparatus such as an image reading apparatus.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-085413, filed May 24, 2023, which is hereby incorporated by reference herein in its entirety.

What is claimed is:

1. A circuit board unit comprising:
a first circuit board having a first signal connector and an inter circuit board connector, the first signal connector and the inter circuit board connector being configured to be capable of outputting a first signal; and
a second circuit board having a second signal connector configured to be capable of outputting a second signal,
wherein in a connector inserting and pulling direction of the first signal connector, the first circuit board and the second circuit board are disposed overlapping with each other such that the second circuit board covers a connector outlet of the first circuit connector,
wherein the first signal is input from the first circuit board to the second circuit board via the inter circuit board connector, and
wherein the second signal connector outputs the first signal and the second signal.

2. The circuit board unit according to claim 1,
wherein the first signal connector is not connected to a connection target outside the first circuit board.

3. The circuit board unit according to claim 1,
wherein the first signal includes a signal for controlling a first load and the second signal includes a signal for controlling a second load.

4. The circuit board unit according to claim 1,
wherein power for driving the second circuit board is supplied from the first circuit board to the second circuit board via the inter circuit board connector.

5. The circuit board unit according to claim 4,
wherein the inter circuit board connector includes:
a first inter circuit board connector that transmits the first signal, and
a second inter circuit board connector that transmits the power.

6. The circuit board unit according to claim 1,
wherein the inter circuit board connector is disposed to be distanced from the edges of the first circuit board in a direction perpendicular to the connector inserting and pulling direction for a distance according to a distance between the first circuit board and the second circuit board in the connector inserting and pulling direction.

7. A circuit board unit comprising a first circuit board having a first signal connector and an inter circuit board connector, the first signal connector and the inter circuit board connector being configured to be capable of outputting a first signal,
wherein only one of the first signal connector and the inter circuit board connector is exclusively connected to an outside of the first circuit board.

8. The circuit board unit according to claim 7,
wherein the other of the first signal connector and the inter circuit board connector is not connected to a connection target outside the first circuit board.

9. An image forming apparatus comprising:
the circuit board unit according to claim 1, and
an apparatus main body that accommodates the circuit board unit.

10. The image forming apparatus according to claim 9, further comprising:
a first motor, and
a second motor,
wherein the first signal includes a signal for controlling the first motor and the second signal includes a signal for controlling the second motor.

11. An image forming apparatus comprising:
the circuit board unit according to claim 7, and
an apparatus main body that accommodates the circuit board unit.
